(19) United States
(12) Patent Application Publication
(10) Pub. No.: US 2009/0121973 A1
(43) Pub. Date: May 14, 2009

(54) Display device and method of fabricating the same

(76) Inventors: Hyung-Soo Kim, Suwon-si (KR); Ki-Wook Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/232,039

(22) Filed: Sep. 10, 2008

(30) Foreign Application Priority Data
Nov. 8, 2007 (KR) 10-2007-0113658

(51) Int. Cl. G09G 3/20

(52) U.S. Cl. 345/55

(57) ABSTRACT

A display device includes a pixel unit, the pixel unit including at least one pixel having a control line coupled thereto, the control line being configured to supply a control signal to the pixel, a data line configured to supply a data signal to the pixel, and at least one buffer circuit disposed in the pixel unit and coupled to the control line.

### BACKGROUND OF THE INVENTION

1. Field of the Invention

Embodiments relate to a display device and a method of fabricating the same, in which the display device is configured to reduce or eliminate distortion of a control signal transmitted to pixels.

2. Description of the Related Art

As display devices are made larger and with higher resolutions, it may be necessary to increase the length and/or reduce the width of wires used to transmit signals in a display panel of the display device. Further, as the wires become more heavily loaded, the signals carried on the wires may be delayed and/or distorted. For example, control signals, such as a scan signal for selectively supplying a data signal to pixels and/or a light-emission control signal for selectively allowing the pixels to emit light, may be distorted. As a result, the display device may not operate properly. Additionally, the long wires in the display panel may produce an antenna effect, which may cause the deterioration of panel characteristics and/or the reduction of manufacturing yields due to substrate damage. Accordingly, there is a need for advances in the art of display devices that enable the formation of large and/or high resolution panels.

### SUMMARY OF THE INVENTION

Embodiments are therefore directed to a display device and a method of fabricating the same, which substantially overcome one or more of the problems due to the limitations and disadvantages of the related art.

It is therefore a feature of an embodiment to provide a display device, and a method of fabricating the same, having buffer circuits in a display panel.

It is therefore another feature of an embodiment to provide a display device, and a method of fabricating the same, having control lines formed of dissimilar conductive materials.

At least one of the above and other features and advantages may be realized by providing a display device, including a pixel unit, the pixel unit including at least one pixel having a control line coupled thereto, the control line being configured to supply a control signal to the pixel, a data line configured to supply a data signal to the pixel, and at least one buffer circuit disposed in the pixel unit and coupled to the control line.

The control line may include at least one of a scan line configured to supply a scan signal to the pixel or a light-emission control line configured to supply a light-emission control signal to the pixel.

The buffer circuit may include first and second inverters, the control line may include a first portion coupled to an input terminal of the first inverter and a second portion coupled to an output terminal of the second inverter, the first portion of the control line may be formed of a first conductive material, and the second portion of the control line may be formed of a second conductive material that is different from the first conductive material. The first portion of the control line and the input terminal of the first inverter may be in a first layer of the buffer circuit, and the second portion of the control line and the output terminal of the second inverter may be in a second layer of the buffer circuit, the second layer being different from the first layer. The first layer may be below the second layer.

Gate electrodes of transistors in the first inverter may be formed of the first conductive material, and source/drain electrodes of transistors in the second inverter may be formed of the second conductive material. A portion of the control line may be formed of a same material as a gate electrode of a transistor in the pixel.

The first and second inverters may each have transistors of different conductivity types coupled in series between a first power source and a second power source, the first and second inverters being coupled to each other, the first portion of the control line may be coupled to gate electrodes of transistors in the first inverter, the second portion of the control line may be coupled to source/drain electrodes of transistors in the second inverter, and the first and second portions of the control line may be electrically coupled by the buffer circuit.

A plurality of buffer circuits may be disposed in the pixel unit, a plurality of control lines may be disposed in rows in the pixel unit, and the buffer circuits may be disposed in an intermediate portion of each of the control lines. The pixel unit may include a first power line configured to supply a first power source to the buffer circuits, the pixel unit may include a second power line configured to supply a second power source to the buffer circuits, and the first and second power lines may be disposed on opposite sides of the pixel circuits, the first and second power lines extending from a top row of the pixel unit to a bottom row of the pixel unit in a column direction.

The buffer circuits may be disposed in a zig-zag manner, such that buffer circuits disposed above one another in a column direction are separated by at least one row. The pixel unit may include a first power line configured to supply a first power source to buffer circuits coupled to a predetermined row of pixels, the pixel unit may include a second power line configured to supply a second power source to the buffer circuits of the predetermined row of pixels, the first and second power lines may be disposed above the predetermined row of pixels, and the first and second power lines may receive the first and second power sources from both sides of the pixel unit.

The buffer circuits may be disposed in a checkerboard pattern, such that buffer circuits in a same row are spaced apart by at least one column, and buffer circuits in a same column are spaced apart by at least one row. The pixel unit may include a first power line configured to supply a first power source to the buffer circuits, the pixel unit may include a second power line configured to supply a second power source to the buffer circuits, and a layout pattern of the first power lines may alternate with a layout pattern of the second power lines. The pixel unit may include a first power line configured to supply a first power source to the buffer circuits, the pixel unit may include a second power line configured to supply a second power source to the buffer circuits, and the first and second power lines may be disposed in a mesh in the pixel unit.

### BRIEF DESCRIPTION OF THE DRAWINGS

The above and other features and advantages will become more apparent to those of ordinary skill in the art by describing in detail example embodiments with reference to the attached drawings, in which:

FIG. 1 illustrates a schematic view of a display device according to a first example embodiment;

FIG. 2 illustrates a buffer circuit in a pixel unit of the display device illustrated in FIG. 1;

FIG. 3 illustrates a cross-sectional view of the buffer circuit illustrated in FIG. 2;

FIG. 4 illustrates a plan view of an arrangement of buffer circuits in a pixel unit according to a second example embodiment;

FIG. 5 illustrates a plan view of an arrangement of buffer circuits in a pixel unit according to a third example embodiment; and

FIG. 6 illustrates a plan view of an arrangement of buffer circuits in a pixel unit according to a fourth example embodiment.

### DETAILED DESCRIPTION OF THE INVENTION

Korean Patent Application No. 10-2007-0113658, filed on Nov. 8, 2007, in the Korean Intellectual Property Office, and entitled: “Organic Light Emitting Display Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not.

As used herein, the expression “or” is not an “exclusive or” unless it is used in conjunction with the term “either.” For example, the expression “A, B, or C” includes A alone; B alone; C alone; both A and B together; both A and C together; both B and C together; and all three of A, B and, C together, whereas the expression “either A, B, or C” means one of A alone, B alone, and C alone, and does not mean any of both A and B together; both A and C together; both B and C together; and all three of A, B and C together.

As used herein, the terms “a” and “an” are open terms that may be used in conjunction with singular items or with plural items. For example, the term “a metal” may represent a single compound, e.g., tungsten, or multiple compounds in combination, e.g., tungsten mixed with chromium.

FIG. 1 illustrates a schematic view of a display device according to a first example embodiment.

Referring to FIG. 1, the display device may be, e.g., an organic light emitting display device, and may include a pixel unit 10 having a plurality of light emitting elements, e.g., organic light emitting diodes (OLEDs).

The pixel unit 10 may be formed on a display substrate, e.g., a substrate that is transparent to visible light, and may include a plurality of pixels 11 disposed at the intersections of control lines (CL) and data lines (D). The control lines (CL) may be disposed between the pixels 11, and may extend in a first direction (a horizontal or row direction) to supply a control signal to the pixels 11. The control lines (CL) may include, e.g., scan lines and/or light-emission control lines. The data lines (D) may be disposed between the pixels 11, and may extend in a second direction (a vertical or column direction) that intersects the first direction to supply a data signal to the pixels 11.

The pixel unit 10 may display an image corresponding to a control signal supplied from the control lines (CL), a data signal supplied from the data lines (D), and first and second pixel power sources ELVDD and ELVSS, respectively, which may be externally supplied.

The organic light emitting display device may further include a scan driver 20 and a data driver 30 coupled to and driving the pixel unit 10. The scan driver 20 and the data driver 30 may be formed on respective driver substrates. The scan driver 20 may generate a control signal, e.g., a scan signal and/or a light-emission control signal, for controlling the pixels 11 to correspond to an externally supplied scan driver control signal. The scan driver 20 may then supply the generated control signal to one or more of the control lines (CL).

The data driver 30 may generate a data signal to correspond to externally supplied data and a data control signals. The data driver 30 may then supply the generated data signal to the data lines (D).

In the organic light emitting display device, the control lines (CL) and data lines (D) controlling the pixels 11 may be arranged over the entire region of the pixel unit 10 in a row direction and a column direction, respectively. If the organic light emitting display device is manufactured with a large scale or with a high resolution, wires of the control lines (CL) for supplying a control signal to the pixels 11 may increase in length and/or decrease in width. In this case, the control lines (CL) may become heavily loaded, and thus a control signal transmitted on the control lines (CL) may be delayed. As a result, a distorted control signal may be supplied to some of the pixels 11, particularly the pixels 11 disposed at the greatest distance from the drive circuit, e.g., the scan driver 20, that supplies the control signal. Such distorted control signals may cause the organic light emitting display device to operate improperly.

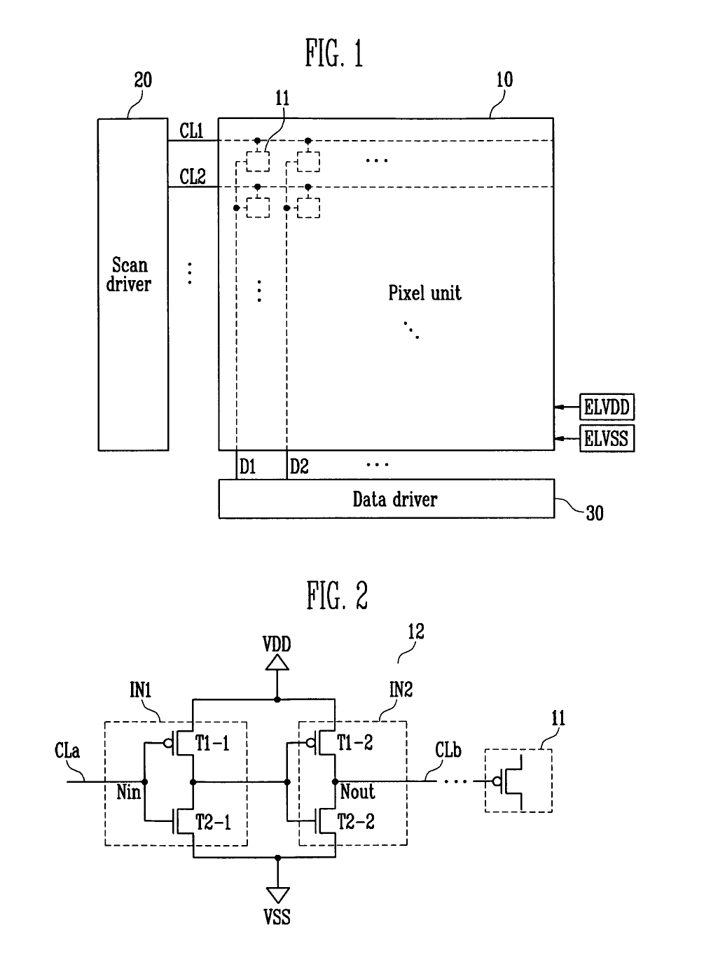

In order to reduce or avoid problems arising from distorted control signals, one or more buffer circuits 12 (see FIG. 2) may be implemented for each of the control lines (CL) disposed in the pixel unit 10 to compensate for the delay of the control signals. The buffer circuits 12 may be formed by the row, and may be disposed to compensate for a delayed control signal passing through the control lines (CL). The buffer circuits 12 may be disposed between the pixels 11 and may be formed in the pixel unit 10.

FIG. 2 illustrates a buffer circuit 12 in the pixel unit 10 of the display device illustrated in FIG. 1.

Referring to FIG. 2, the buffer circuit 12 may include first and second inverters (IN1 and IN2) coupled together between a first power source (VDD) and a second power source (VSS). The first power source (VDD) and the second power source (VSS) may be drive power sources for the buffer circuits 12. The voltages of the first and second power sources VDD, VSS may be set to the voltages of the drive power sources of the scan driver 20, or to the voltages of other drive power sources, etc.

The first inverter (IN1) may be coupled to an input terminal via an input node Nin of the buffer circuit 12, and the second inverter (IN2) may be coupled to an output terminal of the buffer circuit 12 via an output node Nout. In an implementation, a plurality of inverters (not shown) may be further provided between the first inverter (IN1) and the second inverter (IN2). The inverters are preferably disposed in pairs.

Each of the inverters (IN1 and IN2) may include transistors (T) of different conductivity types, which may be coupled in series between the drive power sources, e.g., between the first power source (VDD) and the second power source (VSS). For example, a P-type first transistor (T1) may be coupled to the first power source (VDD), and an N-type second transistor (T2) may be coupled to the second power source (VSS).

Each of the control lines (CL) may have first and second portions (CLa) and (CLb) coupled via the corresponding buffer circuit 12 in a region the buffer circuits 12 are disposed. Thus, the first and second portions (CLa and CLb) of the control lines (CL) may be electrically coupled via the buffer circuit 12.

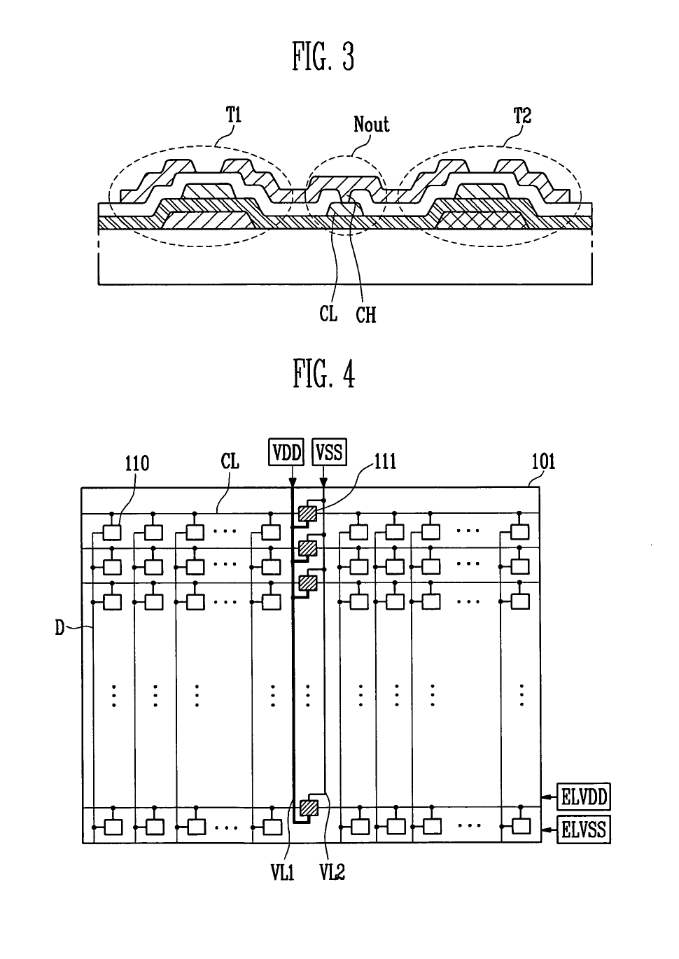

FIG. 3 illustrates a cross-sectional view of the buffer circuit illustrated in FIG. 2.

Referring to FIGS. 2 and 3, the first and second portions (CLa and CLb) of the control lines (CL) may be physically separated at the buffer circuit 12, with an end portion of the first portion (CLa) being coupled to the input terminal of the first inverter (IN1), and an end portion of the second portion (CLb) being coupled to the output terminal of the second inverter (IN2). The first and second portions (CLa and CLb) of the control lines (CL) may be formed of dissimilar conductive materials.

An input terminal of the buffer circuit 12, i.e., an input terminal of the first inverter (IN1), may be coupled to gate electrodes (G) of first and second transistors (T1-1 and T2-1) of the first inverter (IN1). Accordingly, the first portion (CLa) of the control line (CL) and the input terminal of the buffer circuit 12 may be formed of the same conductive material and in the same layer, and may be formed at the same time. For example, the first portion (CLa) of the control line (CL) may be formed of gate electrode metal used for the gate electrodes (G) of the first and second transistors (T1-1 and T2-1) of the first inverter IN1.

The output terminal of the buffer circuit 12, i.e., the output terminal of the second inverter (IN2), may be connected to source/drain electrodes of the first and second transistors (T1-2 and T2-2) of the second inverter (IN2). An output node (Nout) of the buffer circuit may be formed by the electrical coupling of the control line (CL) and the output terminal. In an implementation, the output terminal of the buffer circuit 12 may be formed of different conductive materials and in a different layer from the control line (CLa) and the input terminal of the buffer circuit 12. For example, the output terminal of the buffer circuit 12 may be formed of a same metal used for source and drain electrodes, and may be in a different layer from the control lines (CLa) and the input terminal of the buffer circuit. The second portion (CLb) of the control line (CL) may be formed of the same material used for the source/drain electrodes of the transistors (T1-2 and T2-2) of the second inverter (IN2).

As shown in FIG. 2, each control line (CL) may be coupled to a control electrode of a switching element formed in a pixel 11, e.g., the control line (CL) may be coupled to a gate electrode of a pixel transistor in the pixel 11. In an implementation, the portion of the control line (CL) coupled to the gate electrode of the pixel transistor may be formed of the same material as the gate electrode of the pixel transistor.

Each of the control lines (CL) may be electrically coupled through the buffer circuit. For example, a predetermined portion of the control line CL coupled to the output terminal of the second inverter (IN2) may be formed of the source/drain material, and a predetermined portion of the control line (CL) coupled to the gate electrode of the pixel transistor may be formed of the gate material.

The first and second portions (CLa and CLb) of the control lines (CL) may be joined where the buffer circuits 12 are inserted in the control lines (CL). The input terminal and the output terminal of the buffer circuit 12 may be formed of different conductive materials, which may be arranged in different layers.

The material of the control line (CL) may be changed from the source/drain material to the gate material in a predetermined point, e.g., between the end portion of the control line (CL) coupled to the output terminal of the second inverter (IN2) and the end portion of the control line (CL) coupled to the gate electrode of the pixel transistor, through a contact hole (CH), as shown in FIG. 3.

Accordingly, when a control signal supplied to each of the control lines (CL) is provided to the buffer circuit 12 on the first portion (CLa) of the control line (CL) and re-transmitted on the second portion (CLb) of the control line (CL) via the buffer circuit 12, the control signal is transmitted to the control line (CL) via wires formed of at least two different conductive materials. The use of different conductive materials may reduce or prevent an antenna effect, which may be important during fabrication and/or operation of the display device.

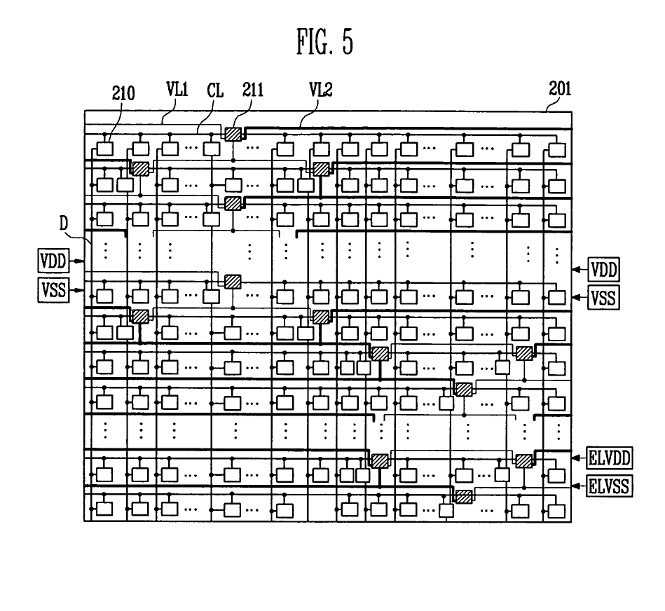

FIG. 4 illustrates a plan view of an arrangement of buffer circuits in a pixel unit according to a second example embodiment.

Referring to FIG. 4, buffer circuits 111 may be disposed in a pixel unit 101 corresponding to rows of respective control lines (CL). The buffer circuits 111 may be the same as the buffer circuits 12 according to the first example embodiment described above. The pixel unit may include pixels 110 driven by the control lines (CL). The pixels 110 may be the same as the pixels 11 according to the first example embodiment described above, and may be supplied with data via data lines (D).

One buffer circuit 111 may be provided for each control line (CL). The buffer circuits 111 in the pixel unit 101 may be disposed to form one column in the center of the pixel unit 101.

The buffer circuits 111 may receive externally-supplied drive power sources, e.g., the first and second power sources (VDD and VSS). To provide power from the first and second power sources (VDD and VSS), respective first and second power lines (VL1 and VL2) may be disposed in the pixel unit 101. The first power line (VL1) may supply the first power source (VDD) to the buffer circuits 111, and the second power line (VL2) may supply the second power source (VSS) to the buffer circuits 111. In an implementation, the first power line (VL1) and the second power line (VL2) may be formed to extend in a column direction on opposite sides of the buffer circuits 111, in the case that the buffer circuits 111 are arranged in the column direction.

By inserting the buffer circuits 111 into the respective control lines (CL) to correct a waveform of the control signal supplied from the left or right side, a distorted signal may be prevented from being transmitted to the pixels 110. Also, the relatively simple arrangement of the buffer circuits 111 facilitates the design of the organic light emitting diode.

The first power line (VL1) and the second power line (VL2) are illustrated with different thicknesses in FIGS. 4, 5 and 6. This is done merely to distinguish the first and second power lines (VL1 and VL2), and is not meant to limit the present invention to power lines of different thicknesses.

FIG. 5 illustrates a plan view of an arrangement of buffer circuits in a pixel unit according to a third example embodiment.

Referring to FIG. 5, buffer circuits 211 may be disposed in predetermined regions of a pixel unit 201. For example, the buffer circuits 211 may be disposed in an upper left region and a lower right region of the pixel unit 201. That is, the buffer circuits 211 may be implemented only in the upper left and lower right regions of the pixel unit 201. In the regions of the pixel unit 201 containing the buffer circuits 211, the buffer circuits 211 may be arranged in a zig-zag manner. For example, the buffer circuits 211 may be disposed in a zig-zag manner in the upper left region, and may be disposed in a zig-zag manner in a lower right region.

Further, the predetermined regions of the pixel unit 201 that include the buffer circuits 211 may themselves be arranged in a zig-zag manner, or may be arranged in diagonal direction across the pixel unit 201. Distances between the buffer circuits 211 may be set using simulation, etc.

The first power line (VL1) for supplying the first power source (VDD) and the second power line (VL2) for supplying the second power source (VSS) may be formed inside the pixel unit 201, since the buffer circuits 211 may be driven by the first and second power sources (VDD and VSS) from the outside. The first and second power lines (VL1 and VL2) may extend in a row direction above the pixels 210 that are driven by the corresponding buffer circuits 211. The power lines (VL) of a same type in adjacent rows may be disposed to be coupled to each other. The first and second power lines (VL1 and VL2) may receive first and second power sources (VDD and VSS) from both sides of the pixel unit 201, and may transmit the first and second power sources (VDD and VSS) to corresponding buffer circuits 211 coupled to the first and second power lines (VL1 and VL2).

According to the third example embodiment, it may be possible to reduce or prevent the transmission of a distorted control signal by inserting the buffer circuits 211 into respective control lines (CL). Buffer circuits 211 in continuous rows may not be disposed in one column, and instead may be distributed throughout the pixel unit 201. Accordingly, the buffer circuits 211 may be prevented from appearing as a dark line on the display device. Thus, according to the third example embodiment, it may be possible to prevent not only the distortion of a control signal supplied through the control lines (CL), but also the deterioration of image quality.

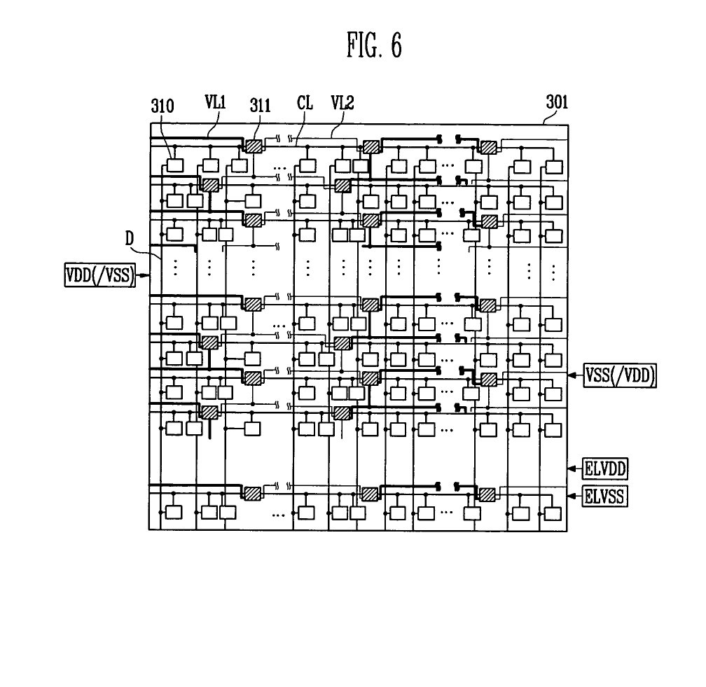

FIG. 6 illustrates a plan view of an arrangement of buffer circuits in a pixel unit according to a fourth example embodiment.

Referring to FIG. 6, buffer circuits 311 may be disposed at regular intervals in each of control lines (CL), e.g., in a checkerboard pattern. Further, the buffer circuits 311 may be distributed so that they are not disposed in one column.

The first power line (VL1) for supplying the first power source (VDD) and the second power line (VL2) for supplying the second power source (VSS) may be formed inside the pixel unit 301. The first and second power lines (VL1 and VL2) may extend in a row direction and may be disposed above pixels 310 of corresponding buffer circuits 311.

Layout regions of first and second power lines (VL1 and VL2) may alternate. For example, as shown in FIG. 6, a first column-shaped layout region in the left-most portion of the pixel unit 310 may include first power lines VL1, a second column-shaped layout region directly adjacent to the first layout region may include second power lines VL2, a third column-shaped layout region directly adjacent to the second layout region may include first power lines VL1, etc., such that the power lines (VL) are formed in respective alternating column-shaped regions. In another implementation, the first and second power lines (VL1 and VL2) may be disposed in a mesh. The first and second power lines (VL1 and VL2) may receive first and second power sources (VDD and VSS) from one side or both sides of the pixel unit 301, and may transmit the first and second power sources (VDD and VSS) to the buffer circuits 311 that are coupled to the first and second power lines (VL1 and VL2).

According to the above-described fourth example embodiment, the buffer circuits 311 may be inserted into respective control lines (CL) to prevent a distorted signal from being transmitted to the pixels 310. In particular, a plurality of the buffer circuits 311 may be inserted into the respective control lines (CL) and spaced apart at regular intervals, so that it may be possible to effectively correct a control signal delayed via the control lines (CL). Therefore, the control signal may be transmitted to any pixel 310 in the pixel unit 301 with little or no distortion. Consequently, it may be possible to effectively prevent poor driving caused by the distortion of a control signal.

Also, the buffer circuits 211 in directly adjacent rows may not be disposed in a same column, but instead may be distributed throughout the pixel unit 201. Accordingly the buffer circuits 211 may be prevented from appearing as a dark line when an image is displayed. Thus, according to the fourth example embodiment, it may be possible to prevent not only the distortion of a control signal supplied through the control lines (CL), but also the deterioration of image quality. In addition, because the buffer circuits 311 according to the fourth example embodiment may be arranged in a predetermined repeating pattern, the layout of buffer circuits 311 may be expanded as required by the size of the pixel unit 301. Accordingly, it may be possible to compensate the distortion of a control signal uniformly throughout the pixel unit 301, while easily scaling the layout for a large-sized panel.

FIGS. 4 to 6 show that the buffer circuits 111, 211, and 311 are not overlapped with the pixels 110, 210, and 310. However, the present invention is not limited thereto, and at least a portion of the buffer circuits 111, 211, and 311 may be overlapped with the pixels 110, 210, 310. For example, if the pixels 110, 210, 310 each include an organic light emitting diode (OLED) and a pixel circuit for driving the organic light emitting diode (OLED), the buffer circuits 111, 211, 311 may be disposed between the pixel circuits of the adjacent pixels 110, 210, 310 on both their sides so as not to overlap with the pixel circuits. However, at least a portion of the organic light emitting diode (OLED) formed in an upper layer, above the pixel circuit, may overlap with at least a portion of the buffer circuits 111, 211, 311.

In detail, a switching transistor, a driving transistor, and a capacitor that form a pixel circuit may be shifted by a predetermined distance so as not to overlap with the buffer circuits 111, 211, 311 in a region in which the buffer circuits 111, 211, 311 are disposed. Also, such a shift of the pixel circuits may not be limited to those pixels 110, 210, 310 that are adjacent to the buffer circuits 111, 211, 311. For example, all of the pixel circuits may be shifted uniformly throughout the pixel units 101, 201, 301 on the basis of the buffer circuits 111, 211, 311. However, the organic light emitting diodes (OLEDs) may be disposed to maintain their positions, without being shifted, as compared to when the buffer circuits 111, 211, 311 are not formed. In this case, a portion of the organic light emitting diodes (OLED) of pixels 110, 210, 310 disposed on both sides of the buffer circuits 111, 211, 311 may be disposed to overlap with a portion of the buffer circuits 111, 211, 311. When the pixel units 101, 201, 301 are top emitting, i.e., emit light in a direction opposite to the pixel circuits, a region in which the buffer circuit 111, 211, 311 are formed may not appear as a dark point or a dark line. Thus, the buffer circuit 111, 211, 311 may be placed in the pixel units 101, 201, 301 so as to partially overlap with organic light emitting diodes (OLED) of adjacent pixels 110, 210 310, thereby preventing the deterioration of image quality.

As described above, an organic light emitting display device according to embodiments may compensate a control signal, which may be delayed while passing through the control lines, using buffer circuits inserted into each of the control lines arranged in the pixel unit. Therefore, poor driving of pixels may be reduced or prevented by avoiding application of a distorted control signal to each of the pixels. Each of the control lines may maintain electrical coupling over the entire panel through the buffer circuits, and an input terminal and an output terminal of the buffer circuit may be formed of different conductive materials disposed in different layers. Accordingly, while a control signal supplied to each of the control lines is re-transmitted to the control lines via the buffer circuits, the control signal may be re-transmitted to the control lines via control wires formed of at least two different conductive materials. The different conductive materials may prevent an antenna effect. In addition, the organic light emitting display device may avoid deterioration of image quality by placing the buffer circuits in predetermined layouts across the pixel unit. These features may be used to implement a display device having a digital drive mode, and having pixels with a relatively simple configuration.

Example embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope as set forth in the following claims.

What is claimed is:

1. A display device, comprising:
a pixel unit, the pixel unit including:
at least one pixel having a control line coupled thereto, the control line being configured to supply a control signal to the pixel;
a data line configured to supply a data signal to the pixel; and
at least one buffer circuit disposed in the pixel unit and coupled to the control line.

2. The display device as claimed in claim 1, wherein the control line includes at least one of a scan line configured to a supply scan signal to the pixel or a light-emission control line configured to supply a light-emission control signal to the pixel.

3. The display device as claimed in claim 1, wherein:
the buffer circuit includes first and second inverters,
the control line includes a first portion coupled to an input terminal of the first inverter and a second portion coupled to an output terminal of the second inverter,
the first portion of the control line being formed of a first conductive material, and
the second portion of the control line being formed of a second conductive material that is different from the first conductive material.

4. The display device as claimed in claim 3, wherein:
the first portion of the control line and the input terminal of the first inverter are in a first layer of the buffer circuit, and
the second portion of the control line and the output terminal of the second inverter are in a second layer of the buffer circuit, the second layer being different from the first layer.

5. The display device as claimed in claim 4, wherein the first layer is below the second layer.

6. The display device as claimed in claim 3, wherein:
gate electrodes of transistors in the first inverter are formed of the first conductive material, and
source/drain electrodes of transistors in the second inverter are formed of the second conductive material.

7. The display device as claimed in claim 6, wherein a portion of the control line is formed of a same material as a gate electrode of a transistor in the pixel.

8. The display device as claimed in claim 3, wherein:
the first and second inverters each have transistors of different conductivity types coupled in series between a first power source and a second power source, the first and second inverters being coupled to each other,
the first portion of the control line is coupled to gate electrodes of transistors in the first inverter,
the second portion of the control line is coupled to source/drain electrodes of transistors in the second inverter, and
the first and second portions of the control line are electrically coupled by the buffer circuit.

9. The display device as claimed in claim 1, wherein:
a plurality of buffer circuits are disposed in the pixel unit,
a plurality of control lines are disposed in rows in the pixel unit, and
the buffer circuits are disposed in an intermediate portion of each of the control lines.

10. The display device as claimed in claim 9, wherein:
the pixel unit includes a first power line configured to supply a first power source to the buffer circuits,
the pixel unit includes a second power line configured to supply a second power source to the buffer circuits, and
the first and second power lines are disposed on opposite sides of the pixel circuits, the first and second power lines extending from a top row of the pixel unit to a bottom row of the pixel unit in a column direction.

11. The display device as claimed in claim 9, wherein the buffer circuits are disposed in a zig-zag manner, such that buffer circuits disposed above one another in a column direction are separated by at least one row.

12. The display device as claimed in claim 11, wherein:
the pixel unit includes a first power line configured to supply a first power source to buffer circuits coupled to a predetermined row of pixels,
the pixel unit includes a second power line configured to supply a second power source to the buffer circuits of the predetermined row of pixels,
the first and second power lines are disposed above the predetermined row of pixels, and
the first and second power lines receive the first and second power sources from both sides of the pixel unit.

13. The display device as claimed in claim 9, wherein the buffer circuits are disposed in a checkerboard pattern, such that buffer circuits in a same row are spaced apart by at least one column, and buffer circuits in a same column are spaced apart by at least one row.

14. The display device as claimed in claim 9, wherein:
the pixel unit includes a first power line configured to supply a first power source to the buffer circuits,
the pixel unit includes a second power line configured to supply a second power source to the buffer circuits, and
a layout pattern of the first power lines alternates with a layout pattern of the second power lines.

15. The display device as claimed in claim 9, wherein:
the pixel unit includes a first power line configured to supply a first power source to the buffer circuits,
the pixel unit includes a second power line configured to supply a second power source to the buffer circuits, and
the first and second power lines are disposed in a mesh in the pixel unit.
